(19) United States
(12) Patent Application Publication
(10) Pub. No.: US 2007/0235858 A1
(43) Pub. Date: Oct. 11, 2007

(54) Mounting assembly for semiconductor devices

(75) Inventor: Satoshi Ohara, Hachioji-shi (JP)

Correspondence Address: Scully, Scott, Murphy & Presser, 400 Garden City Plaza, Garden City, NY, 11530-3319, US

(73) Assignee: OLYMPUS CORPORATION, Tokyo (JP)

(21) Appl. No.: 11/716,230

(22) Filed: Mar. 9, 2007

(30) Foreign Application Priority Data
Apr. 10, 2006 (JP) 2006-107593

(51) Int. Cl. H01L 23/12

(52) U.S. Cl. 257/704

(57) ABSTRACT

A mounting assembly for mounting a semiconductor device includes a package bonded to the semiconductor device via a bonding material, and a lid fixed to the package via a sealing member. A space is defined by the package, the lid and the sealing member to contain the semiconductor device, and is charged with a gas. The bonding area of the semiconductor device and the bonding material, and the bonding area of the package and the bonding material are each smaller than the total area of a lower surface of the semiconductor device.

### CROSS-REFERENCE TO RELATED APPLICATIONS

This application is based upon and claims the benefit of priority from prior Japanese Patent Application No. 2006-107593, filed Apr. 10, 2006, the entire contents of which are incorporated herein by reference.

### BACKGROUND OF THE INVENTION

1. Field of the Invention

The present invention relates to a mounting assembly for mounting semiconductor devices.

2. Description of the Related Art

Jpn. Pat. Appln. KOKAI Publication No. 2004-132792 has proposed a technique related to a mounting assembly, in which a semiconductor device such as a sensor chip is fixed to a package and then sealed. In the proposed technique, the thickness of a joint member for securing the sensor chip to the package is appropriately designed, thereby suppressing deformation of the sensor chip that occurs during a heat treatment for sealing the chip, or when the ambient temperature is changed, and maintaining the degree of vacuum in the sealed package.

### BRIEF SUMMARY OF THE INVENTION

According to a first aspect of the present invention, there is provided a mounting assembly for mounting a semiconductor device comprising: a package bonded to the semiconductor device via a bonding material; and a lid fixed to the package via a sealing member, wherein: a space is defined by the package, the lid and the sealing member to contain the semiconductor device, and is charged with a gas; and a bonding area of the semiconductor device and the bonding material, and a bonding area of the package and the bonding material are each smaller than a total area of a lower surface of the semiconductor device.

According to a first aspect of the present invention, there is provided a mounting assembly for mounting a semiconductor device comprising: a thermal insulation member bonded to the semiconductor device via a semiconductor-device-side bonding material; a package bonded to the thermal insulation member via a package-side bonding material; and a lid fixed to the package via a sealing member, wherein: a space is defined by the package, the lid and the sealing member to contain the semiconductor device, and is charged with a gas; and a bonding area of the semiconductor device and the semiconductor-device-side bonding material, and a bonding area of the semiconductor-device-side bonding material and the thermal insulation member are each smaller than a total area of a lower surface of the semiconductor device.

Advantages of the invention will be set forth in the description which follows, and in part will be obvious from the description, or may be learned by practice of the invention. Advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a sectional view illustrating a mounting assembly for mounting a semiconductor device, according to a first embodiment of the invention;

FIG. 2 is a bottom view of a MEMS device 101 appearing in FIG. 1;

FIG. 3 is a top view of a package 102 appearing in FIG. 1;

FIG. 4 is a sectional view illustrating a mounting assembly for mounting a semiconductor device, according to a second embodiment of the invention;

FIG. 5 is a bottom view of a MEMS device 201 appearing in FIG. 4;

FIG. 6 is a top view of a package 202 appearing in FIG. 4;

FIG. 7 is an enlarged sectional view illustrating package-side metal bumps 207 and MEMS-device-side metal bumps 208 appearing in FIG. 4;

FIG. 8 is a sectional view illustrating a mounting assembly for mounting a semiconductor device, according to a third embodiment of the invention;

FIG. 9 is a bottom view of a MEMS device 301 appearing in FIG. 8;

FIG. 10 is a top view of a package 302 appearing in FIG. 8;

FIG. 11 is a top view of a glass substrate 304 appearing in FIG. 8;

FIG. 12 is a bottom view of a glass substrate 304 appearing in FIG. 8;

FIG. 13 is a view illustrating a case where joining is made at sides of a MEMS device; and

FIG. 14 is a view illustrating a case where joining is made at sides and lower surface of a MEMS device.

### DETAILED DESCRIPTION OF THE INVENTION

Embodiments of the invention will be described with reference to the accompanying drawings.

### First Embodiment

Referring first to FIGS. 1 to 3, a first embodiment of the invention will be described.

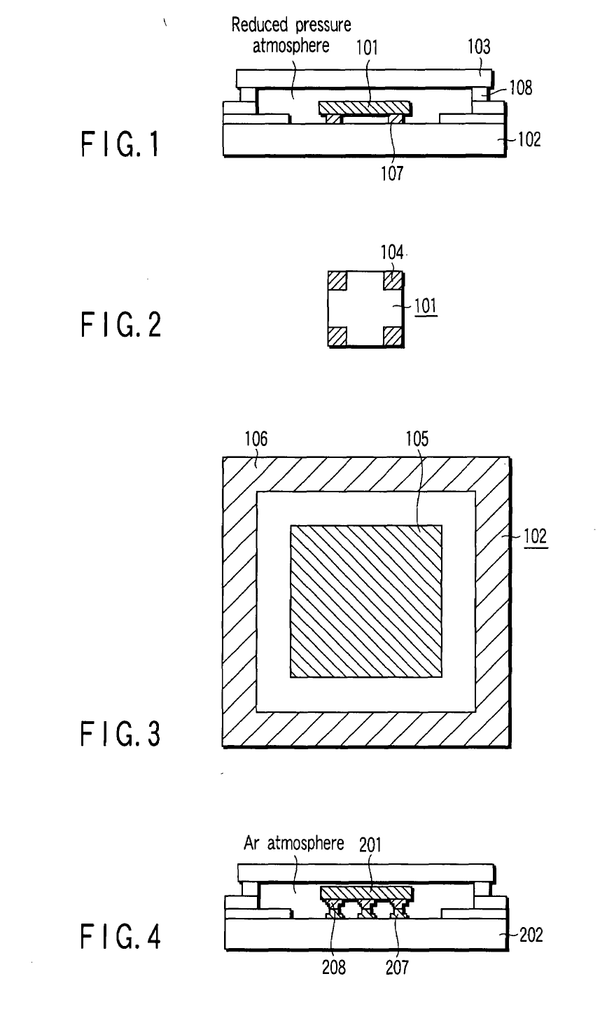

FIG. 1 is a sectional view illustrating a mounting assembly for mounting a semiconductor device, according to the first embodiment of the invention. FIG. 2 is a bottom view of a MEMS device 101 appearing in FIG. 1. FIG. 3 is a top view of a package 102 appearing in FIG. 1.

In the mounting assembly, shown in FIG. 1, for mounting a semiconductor device, MEMS-device-side fixing pads 104 are provided on preset portions of the lower surface of a Micro electro mechanical system (MEMS) device 101 as a semiconductor device example, as is shown in FIG. 2. The number of fixing pads 104 is not limited to that shown in FIG. 2. It is sufficient if the total area of the MEMS-device-side fixing pads is smaller than that of the lower surface of the MEMS device 101.

The MEMS-device-side fixing pads 104 are formed of a laminated thin film including, for example, Ni and Au films. The thin films are formed by, for example, sputtering. The MEMS device 101 is soldered to the package 102 via the MEMS-device-side fixing pads 104.

The package 102 is formed of, for example, a ceramic material, and can be sealed under reduced pressure. Assume here that reduced pressure means pressure at least lower than atmospheric pressure. Further, as shown in FIG. 3, a package-side fixing pad 105 and sealing pad 206 are provided on preset portions of the package 102 for soldering.

As can be understood from FIG. 3, the package-side fixing pad 105 is provided over the entire surface of the package 102, to which the MEMS device 101 is fixed. However, the shape of the package-side fixing pad 105 is not limited to that shown in FIG. 3. The advantage of the first embodiment, described later, can be acquired even when, for example, the package-side fixing pad is divided into a plurality of portions. In this case, the thus-obtained divisions of the package-side fixing pad may be electrically isolated from each other.

To solder the MEMS device 101 to the package 102, MEMS-device fixing solder 107 as a bonding material is supplied to the package-side fixing pad 105 of the package 102. Subsequently, the MEMS-device-side fixing pads 104 of the MEMS device 101 are brought into contact with the package-side fixing pad 105 with the solder 107. After that, the package 102 and MEMS device 101 are heated by a heater (not shown), thereby melting the MEMS-device fixing solder 107 to fix the MEMS device 101 to the package 102.

Preferably, the heater for melting the MEMS-device fixing solder 107 is a pulse heater capable of high-speed temperature rising. Pulse heaters can minimize thermal damage to the MEMS device 101.

Further, in the first embodiment, the total fixing area of the MEMS device 101, i.e., the total area of the MEMS-device fixing solder 107 on the MEMS-device fixing pads 104, is set smaller than that of the lower surface of the MEMS device 101, as is shown in FIG. 2. Accordingly, the heat of the package 102 is not easily transmitted to the MEMS device 101 through the MEMS-device fixing solder 107.

To reduce the total area of the MEMS-device fixing solder 107, it is sufficient if the total area of the MEMS-device fixing pads 104 is reduced. However, if the total area of the MEMS-device fixing pads 104 is reduced too much, the fixing strength of the MEMS device 101 may well be reduced. In terms of this, it is desirable that the total area of the MEMS-device fixing pads 104 be minimized within a range in which the MEMS device 101 secures a sufficient fixing strength. Based on the result of experiments made by the inventor, the total area of the MEMS-device fixing pads 104 is set to about ⅓ of the entire lower surface of the MEMS device 101.

As described above, the thermal transmission area of the MEMS device 101 can be reduced by reducing the total area of portions of the MEMS device 101 to be secured to the package 102. Further, if, in a sealing process, described later, the ambient space of the MEMS device 101 is set under reduced pressure, the amount of heat transmitted to the MEMS device 101 can be significantly reduced. For these reasons, thermal damage to the MEMS device 101 due to the heat emitted during heating in the sealing process or due to changes in ambient temperature can be reduced.

Although in the first embodiment, the MEMS device 101 and package 102 are soldered to each other, they may be bonded by heating and pressurizing metal paste.

A description will now be given of a sealing process for sealing the MEMS device 101 of FIG. 1 under a reduced pressure.

In the sealing process, the MEMS device 101 is sealed under reduced pressure using a lid 103 and sealing solder 108, with the MEMS device 101 fixed to the package 102 by the MEMS-device-fixing solder 107.

To this end, firstly, the sealing solder 108 as a sealing material is supplied to a sealing pad 106 incorporated in the package 102. Subsequently, the pressure around the package 102 is reduced, thereby reducing the pressure of the space defined by the package 102 and lid 103. In this state, the upper surface of the lid 103 and the lower surface of the package 102 are heated by a pulse heater, thereby melting the sealing solder 108. In the first embodiment, thermal damage to the MEMS device 101 due to the heat emitted during heating or due to changes in ambient temperature can be reduced for the reasons stated above.

After melting the sealing solder 108, the package 102 and lid 103 are cooled to harden the solder 108, and the pressure outside the package 102 is returned to atmospheric pressure, which is the termination of the sealing process.

### Second Embodiment

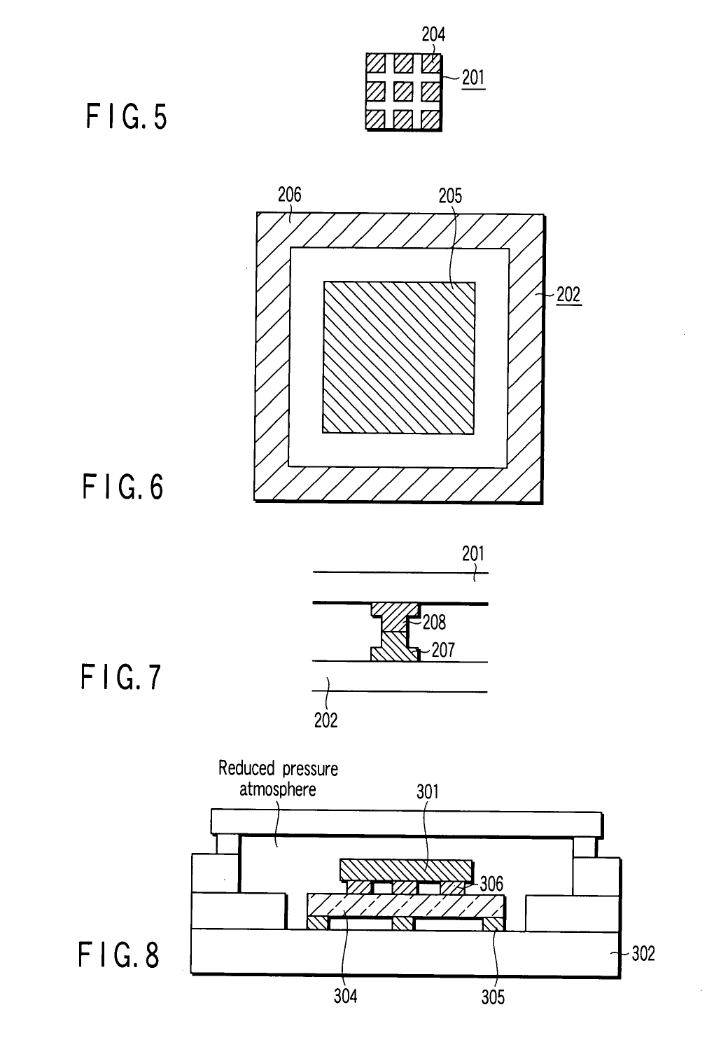

Referring then to FIGS. 4 to 7, a second embodiment will be described. FIG. 4 is sectional view illustrating a mounting assembly for mounting a semiconductor device, according to a second embodiment of the invention. FIG. 5 is a bottom view of a MEMS device 201 appearing in FIG. 4. FIG. 6 is a top view of a package 202 appearing in FIG. 4. FIG. 7 is an enlarged sectional view illustrating package-side metal bumps 207 and MEMS-device-side metal bumps 208 appearing in FIG. 4.

In the second embodiment described below, elements similar to those of the first embodiment are not described.

In the mounting assembly, shown in FIG. 4, for mounting a semiconductor device, MEMS-device-side fixing pads 204 are provided on preset portions of the lower surface of a MEMS device 201 as a semiconductor device example, as is shown in FIG. 5.

A package 202 is formed of, for example, a ceramic material, and can be sealed in an atmosphere of Ar having a lower thermal conductivity than air. As shown in FIG. 6, a package-side fixing pad 205 and sealing pad 206 are provided on preset portions of the package 202.

In the second embodiment, the MEMS-device-side fixing pads 204 and package-side fixing pad 205 are formed of, for example, Al thin films, and the sealing pad 206 is formed of a laminated thin film including, for example, Ni and Au films. The thin films are formed by, for example, sputtering.

To solder the MEMS device 201 to the package 202, firstly, MEMS-device-side metal bumps 208 and package-side metal bumps 207 are formed on the MEMS device 201 and package 202, respectively. The bumps 208 and 207 are formed of, for example, Au. After preparing these metal bumps, the MEMS-device-side metal bumps 208 are brought into contact with the package-side metal bumps 207, with the package 202 fixed. After that, the MEMS device 201 is heated and pressurized using a heat head (not shown), thereby bonding the bumps 208 and 207 by thermal pressure. As a result, the MEMS device 201 is secured to the package 202.

Thereafter, the MEMS device 201 is sealed in the atmosphere of Ar in the same process as the sealing process of the first embodiment.

As described above, in the second embodiment, since the MEMS device 201 is secured to the package 202 by the package-side metal bumps 207 and MEMS-device-side metal bumps 208, and the total bonding area of the MEMS device 201 and MEMS-device-side metal bumps 208 as bonding members is suppressed as shown in FIG. 5, thermal damage to the MEMS device 201 due to the heat emitted during heating in the sealing process or due to changes in ambient temperature can be reduced for the same reasons as in the first embodiment.

Further, in the second embodiment, as shown in FIG. 7, the bonding area of each package-side metal bump 207 and corresponding MEMS-device-side metal bump 208 is set smaller than that of each package-side metal bump 207 and the package 202, and than that of each MEMS-device-side metal bump 208 and the MEMS device 201. Accordingly, the cross-sectional area of part of the thermal conducting route ranging from the package 202 to the MEMS device 201 is reduced, therefore the effect of reducing thermal damage to the MEMS device 201 can be further enhanced than in the first embodiment.

In FIG. 7, the bonding area of each package-side metal bump 207 and corresponding MEMS-device-side metal bump 208 is set to a minimum value. However, the thermal conducting route may not always have a minimum cross-sectional area at the bonding portion of each package-side metal bump 207 and corresponding MEMS-device-side metal bump 208. It is sufficient if the cross-sectional area of part of the thermal conducting route is reduced.

Furthermore, in the second embodiment, the package 202 is charged with Ar having a lower thermal conductivity than air. Accordingly, the conduction of heat to the MEMS device 201 can be minimized as in the first embodiment. In the second embodiment, the interior of the package 202 may be set under reduced pressure, or the interior of the package 102 in the first embodiment may be charged with Ar. Also, in the second embodiment, the interior of the package 202 may not always be charged with Ar. Namely, a material such as N₂ or CO₂, which has a lower thermal conductivity than air, may be used instead of Ar.

### Third Embodiment

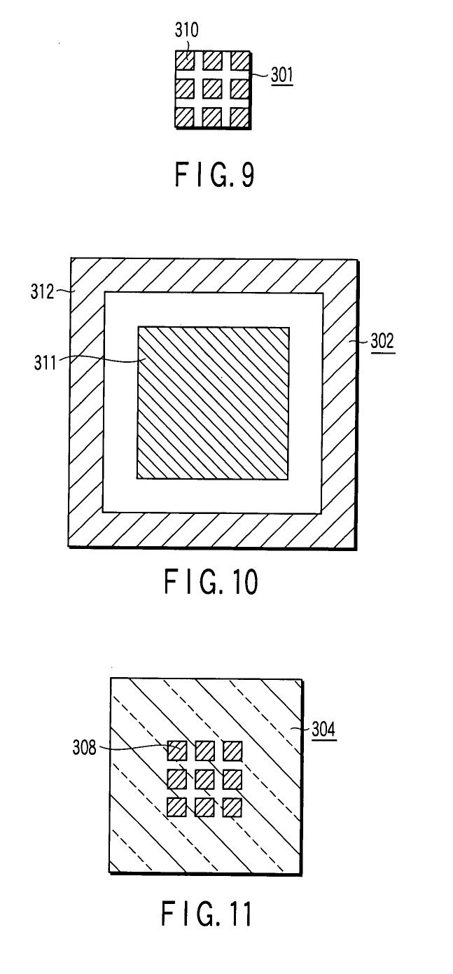

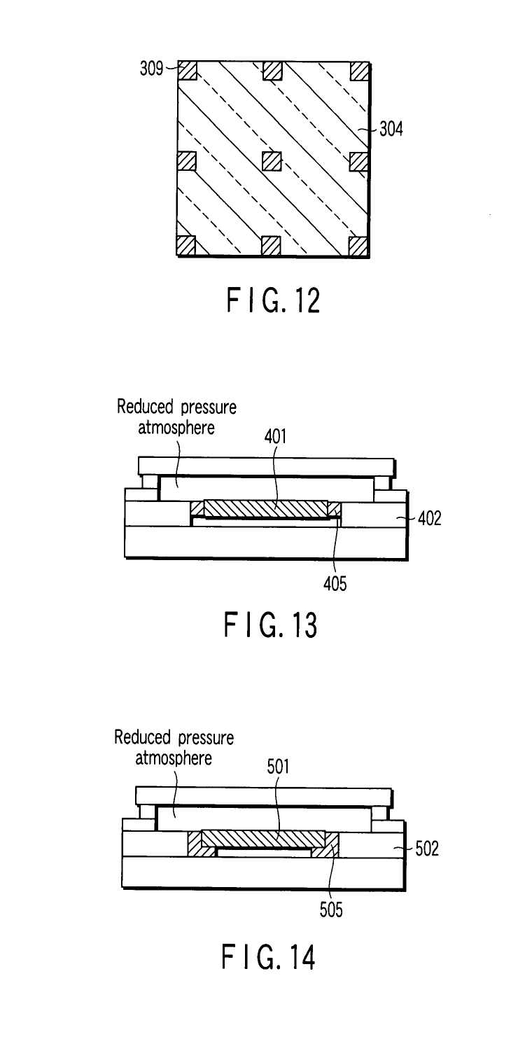

Referring then to FIGS. 8 to 12, a third embodiment of the invention will be described. FIG. 8 is a sectional view illustrating a mounting assembly for mounting a semiconductor device, according to a third embodiment of the invention. FIG. 9 is a bottom view of a MEMS device 301 appearing in FIG. 8. FIG. 10 is a top view of a package 302 appearing in FIG. 8. FIGS. 11 and 12 are top and bottom views of a glass substrate 304 appearing in FIG. 8, respectively.

In the third embodiment described below, elements similar to those in the first or second embodiment are not described.

In the mounting assembly, shown in FIG. 8, for mounting a semiconductor device, MEMS-device-side fixing pads 310 are provided on preset portions of the lower surface of a MEMS device 301 as a semiconductor device example, as is shown in FIG. 9.

A package 302 is formed of, for example, a ceramic material, and can be sealed under reduced pressure. As shown in FIG. 10, a package-side fixing pad 311 and sealing pad 312 are provided on preset portions of the package 302.

A glass substrate 304 as a thermal insulation member is formed of, for example, quartz. As shown in FIG. 11, substrate-upper-side fixing pads 308 for fixing the MEMS device 301 are provided on the upper surface of the glass substrate 304, and substrate-lower-side fixing pads 309 for bonding the package 302 are provided on the lower surface of the glass substrate 304.

In the third embodiment, the MEMS-device-side fixing pads 310, package-side fixing pad 311, sealing pad 312, substrate-upper-side fixing pads 308 and substrate-lower-side fixing pads 309 are formed of, for example, a laminated thin film of Ni and Au thin films. These thin films are formed by, for example, sputtering.

During bonding, firstly, substrate-fixing solder 305 is supplied to the package-side fixing pad 311 on the package 302 to secure the glass substrate 304 to the package 302. The substrate-lower-side fixing pads 309 of the glass substrate 304 are brought into contact with the package-side fixing pad 311 with the substrate-fixing solder 305. After that, the package 302 and glass substrate 304 are heated using a heater head (not shown) to melt the substrate-fixing solder 305 and secure the glass substrate 304 to the package 302.

Subsequently, MEMS-device-fixing solder 306 is supplied to the substrate-upper-side fixing pads 308 on the glass substrate 304 to secure the MEMS device 301 to the glass substrate 304. The MEMS-device-side fixing pads 310 of the MEMS device 301 are brought into contact with the substrate-upper-side fixing pads 308 with the MEMS-device-fixing solder 306. After that, the package 302, glass substrate 304 and MEMS device 301 are heated using the heater head (not shown) to melt the MEMS-device-fixing solder 306 and secure the MEMS device 301 to the glass substrate 304. The subsequent sealing process is performed in the same way as in the first embodiment.

In the third embodiment, the bonding area of the MEMS device 301 and glass substrate 304 is set smaller than the area of the lower surface of the MEMS device 301, and the bonding area of the glass substrate 304 and package 302 is set smaller than the area of the lower surface of the glass substrate 304. Accordingly, thermal damage to the MEMS device 301 due to the heat emitted during heating in the sealing process or due to changes in ambient temperature can be reduced as in the first embodiment.

Further, in the third embodiment, since the glass substrate 304 having a lower thermal conductivity than the MEMS-device-fixing solder 306 and substrate-fixing solder 305 is interposed between the MEMS device 301 and package 302, the effect of reducing thermal damage to the MEMS device 301 can be further enhanced than in the first embodiment.

Although, in FIG. 8, only a single MEMS device is secured to the glass substrate 304, a plurality of MEMS devices may be secured thereto. Further, although the third embodiment employs a glass substrate as a thermal insulation member, a material other than glass may be employed, if it has a lower thermal conductivity than the MEMS-device-fixing solder 306 and substrate-fixing solder 305.

Although the third embodiment employs soldering, it may employ bonding using metal bumps, as in the second embodiment.

In the mounting assemblies of the above-described embodiments, the lower surface of the MEMS device is secured to the package or glass substrate. However, as shown in FIG. 13, side surfaces of a MEMS device 401 may be bonded to a package 402 using MEMS-device-fixing solder 405. In this case, the entire side surfaces of the MEMS device may be bonded. However, to reduce the bonding area, it is preferable that only part of the side surfaces of the MEMS device be bonded.

Furthermore, as shown in FIG. 14, side surfaces and part of the lower surface of a MEMS device 501 may be bonded to a package 502 using MEMS-device-fixing solder 505.

The assemblies of FIGS. 13 and 14 can provide the same advantage as the first to third embodiments.

In addition, although each of the above-described embodiments employs a metal bonding material, such as metal solder or metal bumps, the bonding material is not limited to metal. For instance, a resin material such as an adhesive may be used as a bonding material. Further, to secure a MEMS device or glass substrate to a package, or to secure a MEMS device to a glass substrate, means other than heating or thermal pressure bonding may be employed. Namely, ultrasonic bonding, surface activation bonding, or bonding using an adhesive or melted resin may be employed in accordance with various conditions such as bonding materials.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A mounting assembly for mounting a semiconductor device comprising:
a package bonded to the semiconductor device via a bonding material; and
a lid fixed to the package via a sealing member, wherein:
a space is defined by the package, the lid and the sealing member to contain the semiconductor device, and is charged with a gas; and
a bonding area of the semiconductor device and the bonding material, and a bonding area of the package and the bonding material are each smaller than a total area of a lower surface of the semiconductor device.

2. The mounting assembly according to claim 1, wherein part of the lower surface of the semiconductor device is bonded to the bonding material.

3. The mounting assembly according to claim 1, wherein part or all of a side surface of the semiconductor device is bonded to the bonding material.

4. The mounting assembly according to claim 1, wherein part of a side surface of the semiconductor device and part of the lower surface of the semiconductor device are bonded to the bonding material.

5. The mounting assembly according to claim 1, wherein the charged gas is of reduced pressure lower at least than atmospheric pressure.

6. The mounting assembly according to claim 1, wherein the charged gas contains a material of a thermal conductivity lower than air.

7. The mounting assembly according to claim 1, wherein a minimum cross-sectional area of the bonding material is smaller than a bonding area of the semiconductor device and the bonding material, and than a bonding area of the package and the bonding material.

8. The mounting assembly according to claim 1, wherein the bonding material is a metal material or a resin material.

9. A mounting assembly for mounting a semiconductor device comprising:
a thermal insulation member bonded to the semiconductor device via a semiconductor-device-side bonding material;
a package bonded to the thermal insulation member via a package-side bonding material; and
a lid fixed to the package via a sealing member, wherein:
a space is defined by the package, the lid and the sealing member to contain the semiconductor device, and is charged with a gas; and
a bonding area of the semiconductor device and the semiconductor-device-side bonding material, and a bonding area of the semiconductor-device-side bonding material and the thermal insulation member are each smaller than a total area of a lower surface of the semiconductor device.

10. The mounting assembly according to claim 9, wherein the thermal insulation member has a lower thermal conductivity than the semiconductor-device-side bonding material and the package-side bonding material.

11. The mounting assembly according to claim 9, wherein a bonding area of the package-side bonding material and the thermal insulation member, and a bonding area of the package-side bonding material and the package are each smaller than a total area of a lower surface of the semiconductor device.

12. The mounting assembly according to claim 9, wherein each of the semiconductor-device-side bonding material and the package-side bonding material is a metal material or a resin material.

13. The mounting assembly according to claim 8, wherein the metal material includes one of solder, metal paste, a metal bump and a metal pad.

14. The mounting assembly according to claim 12, wherein the metal material includes one of solder, metal paste, a metal bump and a metal pad.

15. The mounting assembly according to claim 8, wherein the resin material is an adhesive.

16. The mounting assembly according to claim 12, wherein the resin material is an adhesive.
